(19) United States
(12) Patent Application Publication
(10) Pub. No.: US 2024/0332909 A1
(43) Pub. Date: Oct. 3, 2024

(54) NITRIDE SEMICONDUCTOR LIGHT EMISSION ELEMENT

(71) Applicant: SONY GROUP CORPORATION, TOKYO (JP)

(72) Inventor: MASAHIRO MURAYAMA, TOKYO (JP)

(21) Appl. No.: 18/578,021

(22) PCT Filed: Mar. 23, 2022
(86) PCT No.: PCT/JP2022/013340

§ 371 Date: Jan. 10, 2024

(30) Foreign Application Priority Data
Jul. 27, 2021 (JP) 2021-122428

(51) Int. Cl. H01S 5/32; H01S 5/20; H01S 5/30

(52) U.S. Cl. CPC H01S 5/3211; H01S 5/2009; H01S 5/3063

(57) ABSTRACT

A nitride semiconductor light emission element including a substrate having a (0001) plane as a lamination plane, an n-type semiconductor layer, an active layer, a p-type semiconductor layer, and a contact layer in this order, the p-type semiconductor layer including a cladding layer including AlGaN, in which an Al composition (50) of the cladding layer (18) is formed to be smaller as being away from an interface on the substrate side, a Mg concentration (52) of the cladding layer (18) is formed to have a maximum value at the interface (52d) on the substrate side or a maximal value (52a) in a direction of being away from the interface on the substrate side, and the nitride semiconductor light emission element achieves a suppression of light absorption and thus improving laser characteristics, by decreasing the doping amount of Mg by suppressing a memory effect.

### TECHNICAL FIELD

The present disclosure relates to, for example, a structure of a nitride semiconductor light emission element formed on a substrate of a (0001) plane of gallium nitride (GaN).

### BACKGROUND ART

In a semiconductor light emission element, light is emitted by recombination of electrons and positive holes in a well layer of an active layer which is a light-emitting layer. In order to improve such luminous efficiency, it is generally desirable to increase the concentration of electrons and the concentration of positive holes in the well layer. However, since a nitride semiconductor represented by gallium nitride (GaN) has a positive hole mobility smaller than an electron mobility, it is difficult to obtain a high positive hole concentration, and in order to achieve a high-efficiency light-emission element of current injection type, it is necessary to improve positive hole injection efficiency into an active layer.

In order to solve this problem, disclosed are a group III nitride semiconductor light emission element in which an influence of polarization generated by a p-type portion and an n-type portion inside an aluminum gallium nitride (AlGaN) layer due to a change in aluminum (Al) composition in the AlGaN layer is reduced, and light extraction efficiency is improved, and a technique related to a manufacturing method of the group III nitride semiconductor light emission element.

### CITATION LIST

### Patent Document

Patent Document 1: Japanese Patent Application Laid-Open No. 2019-87712

### SUMMARY OF THE INVENTION

### Problems to be Solved by the Invention

However, the technique disclosed in Patent Document 1 needs to control a doping amount while intentionally increasing Mg in the AlGaN layer. In addition, an increase in the doping amount of Mg in a cladding layer increases light absorption, and thus there is a problem that laser characteristics are deteriorated.

The present disclosure has been made in view of such a problem, and an object of the present disclosure is to provide a nitride semiconductor light emission element that has a configuration in which an Al composition of an AlGaN layer that forms a p-type cladding layer is smaller as being away from an interface on a substrate side, or the doping amount of Mg is decreased by suppressing a memory effect through supplying a Mg raw material, optimizing steps, or the like, and thus light absorption is suppressed and laser characteristics are improved.

### Solutions to Problems

The present disclosure is made to solve the above-described problems, and a first aspect of the present disclosure is a nitride semiconductor light emission element including: a substrate having a (0001) plane as a lamination plane; an n-type semiconductor layer; an active layer; a p-type semiconductor layer; and a contact layer in this order, the p-type semiconductor layer including a cladding layer including AlGaN, in which an Al composition of the cladding layer is formed to be smaller as being away from an interface on the substrate side, and a Mg concentration of the cladding layer is formed to have a maximum value at the interface on the substrate side or a maximal value in a direction of being away from the interface on the substrate side.

In addition, in the first aspect, the Mg concentration of the cladding layer may be formed to decrease from the maximum value or the maximal value as being away from the interface on the substrate side.

Furthermore, in the first aspect, the p-type semiconductor layer may include an electron barrier layer including AlGaN, and the Mg concentration of the cladding layer may be formed to have a maximum value on a surface in contact with the electron barrier layer.

In addition, in the first aspect, the Mg concentration of the cladding layer may be formed to decrease from a maximum value formed on a surface in contact with the electron barrier layer as being away from the interface on the substrate side.

Furthermore, in the first aspect, the p-type semiconductor layer may include an electron barrier layer including AlGaN and an intermediate layer including AlGaN in order closer to the substrate having the (0001) plane as the lamination plane than to the cladding layer, and the Mg concentration in the cladding layer may be formed such that either of maximal values in a direction away from a surface in contact with the intermediate layer or the interface on the substrate side makes a maximum value.

In addition, in the first aspect, the Mg concentration of the cladding layer may be formed to be decreased as being away from the surface in contact with the intermediate layer or decreased as being away from the interface on the substrate side from the maximal value.

Furthermore, in the first aspect, the Al composition of the intermediate layer may be formed to be smaller than the Al composition of the electron barrier layer and smaller than the Al composition of the interface of the cladding layer on the substrate side.

Furthermore, in the first aspect, the Al composition of the intermediate layer may be formed to be smaller than the Al composition of the electron barrier layer and smaller than an average value of the Al composition of the cladding layer.

Furthermore, a second aspect of the present disclosure is a nitride semiconductor light emission element including: a substrate having a (0001) plane as a lamination plane; an n-type semiconductor layer; an active layer; a p-type semiconductor layer; and a contact layer in this order, the p-type semiconductor layer including an electron barrier layer including AlGaN, an intermediate layer including GaN, and a cladding layer including AlGaN, in which an Al composition of the cladding layer is formed to be smaller as being away from the interface on the substrate side, and a Mg concentration of the cladding layer is formed to have a maximum value at the interface on the substrate side or a maximal value in a direction of being away from the interface on the substrate side.

Furthermore, a third aspect of the present disclosure is a nitride semiconductor light emission element including: a substrate having a (0001) plane as a lamination plane; an n-type semiconductor layer; an active layer; a p-type semiconductor layer; and a contact layer in this order, the p-type semiconductor layer including a cladding layer including AlGaN, in which an Al composition of the cladding layer is formed to be smaller as being away from the interface on the substrate side, and a Mg concentration of the cladding layer rapidly increases to form a maximal value from the interface on the substrate side, and rapidly decreases to be non-doped from the maximal value.

Furthermore, in the first aspect, the substrate having the (0001) plane as a lamination plane may include any of aluminum nitride (AlN), gallium nitride (GaN), sapphire, or silicon carbide (SiC).

By adopting the above-described aspect, it is possible to provide a nitride semiconductor light emission element that has a configuration in which an Al composition of an AlGaN layer that forms a p-type cladding layer is made to become smaller as being away from the interface on the substrate side, or the doping amount of Mg is decreased by suppressing a memory effect through supplying a Mg raw material, optimizing steps, or the like and thus light absorption is suppressed and laser characteristics are improved.

### BRIEF DESCRIPTION OF DRAWINGS

FIG. 1 is a cross-sectional view illustrating a schematic structure of a basic form of a first embodiment of a nitride semiconductor light emission element according to the present disclosure.

FIG. 2 is a plan view illustrating a schematic structure of the nitride semiconductor light emission element according to the present disclosure.

FIG. 3 is an explanatory view illustrating a relationship between a film thickness and an Al composition, and between a film thickness and a Mg concentration of the p-type semiconductor layer of the basic form of the first embodiment of the nitride semiconductor light emission element according to the present disclosure.

FIG. 4 is a cross-sectional view illustrating a schematic structure of a first modification example of the first embodiment of the nitride semiconductor light emission element according to the present disclosure.

FIG. 5 is an explanatory view illustrating a relationship between a film thickness and an Al composition, and between a film thickness and a Mg concentration of the p-type semiconductor layer of the first modification of the first embodiment of the nitride semiconductor light emission element according to the present disclosure.

FIG. 6 is a cross-sectional view illustrating a schematic structure of a second modification of the first embodiment of the nitride semiconductor light emission element according to the present disclosure.

FIG. 7 is an explanatory view illustrating a relationship between a film thickness and an Al composition, and between a film thickness and a Mg concentration of the p-type semiconductor layer of the second modification of the first embodiment of the nitride semiconductor light emission element according to the present disclosure.

FIG. 8 is an explanatory view illustrating a relationship between a film thickness, an Al composition, and a Mg concentration of the second modification and a comparative example of the first embodiment of the nitride semiconductor light emission element according to the present disclosure.

FIG. 9 is an explanatory diagram of a manufacturing method of the first embodiment of the nitride semiconductor light emission element according to the present disclosure (part 1). FIG. 10 is an explanatory diagram of the manufacturing method of the first embodiment of the nitride semiconductor light emission element according to the present disclosure (part 2).

FIG. 11 is an explanatory diagram of the manufacturing method of the first embodiment of the nitride semiconductor light emission element according to the present disclosure (part 3).

FIG. 12 is an explanatory diagram of the manufacturing method of the first embodiment of the nitride semiconductor light emission element according to the present disclosure (part 4).

FIG. 13 is an explanatory view illustrating a relationship between a film thickness and an Al composition, and between a film thickness and a Mg concentration of the p-type semiconductor layer of a second embodiment of the nitride semiconductor light emission element according to the present disclosure.

### MODE FOR CARRYING OUT THE INVENTION

Next, a mode for carrying out the present disclosure (hereinafter, referred to as an “embodiment”) will be described in the following order with reference to the drawings. In the following drawings, the same or similar parts are denoted by the same or similar reference numerals. However, the drawings are schematic, and dimensional ratios and the like of the respective parts do not necessarily match actual ones. Furthermore, it is needless to say that dimensional relationships and ratios are partly different between the drawings.
1. Basic Form of First Embodiment of Nitride Semiconductor Light Emission Element according to Present Disclosure
2. First Modification of First Embodiment of Nitride Semiconductor Light Emission Element according to Present Disclosure
3. Second Modification of First Embodiment of Nitride Semiconductor Light Emission Element according to Present Disclosure
4. Manufacturing Method of First Embodiment of Nitride Semiconductor Light Emission Element according to Present Disclosure
5. Second Embodiment of Nitride Semiconductor Light Emission Element according to Present Disclosure
6. Manufacturing Method of Second Embodiment of Nitride Semiconductor Light Emission Element according to Present

### Disclosure

<1. Basic Form of First Embodiment of Nitride Semiconductor Light Emission Element according to Present Disclosure>

### [Configuration of Basic Form of First Embodiment]

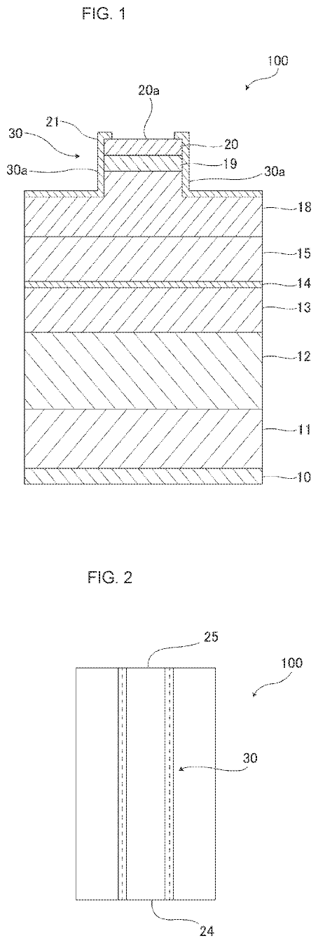

Hereinafter, a basic form of a first embodiment of a nitride semiconductor light emission element 100 according to the present disclosure will be described with reference to FIGS. 1 and 2. FIG. 1 is a cross-sectional view of the nitride semiconductor light emission element 100 according to the present basic form as viewed from a front end surface 24 side which is a light emission end surface. As illustrated in FIGS. 1 and 2, the nitride semiconductor light emission element 100 according to the present disclosure is formed in a substantially convex shape in a cross-sectional view with a ridge portion 30 protruding in a ridge shape at a top.

The ridge portion 30 is formed by removing both side surfaces of a contact layer 19 and a second cladding layer 18 by etching such as reactive ion etching (RIE) method, or the like. A width (direction orthogonal to a resonator direction) of the ridge portion 30 is, for example, 500 nm to 100 μm. A region sandwiched between the front end surface 24 and a rear end surface 25 of the ridge portion 30 forms a reflector. That is, a resonator that amplifies light by reciprocating laser light between the front end surface 24 and the rear end surface 25 is configured. A distance (resonator length) between the front end surface 24 and the rear end surface 25 is, for example, 50 μm to 3000 μm.

Both side surfaces 30a and 30a of the ridge portion 30 and an upper surface of the second cladding layer 18 are covered with an insulating layer 21. The insulating layer 21 includes, for example, silicon dioxide (SiO₂) and silicon nitride (Si₃N₄). The film thickness is, for example, 10 nm to 500 nm.

In the nitride semiconductor light emission element 100, a first cladding layer 12, a first light guide layer 13, an active layer 14, a second light guide layer 15, the second cladding layer 18, and a contact layer 19 are sequentially laminated on a GaN substrate 11 having a (0001) plane as a lamination plane. Then, a first electrode 10 as a cathode is formed on a lower surface of the GaN substrate 11, and a second electrode 20 as an anode is formed on an upper surface of the contact layer 19.

The GaN substrate 11 forms a base for laminating each of the layers included in the nitride semiconductor light emission element 100, and for example, includes gallium nitride (GaN) for use as the substrate having the (0001) plane as the lamination plane. Furthermore, in the following embodiment, the GaN substrate 11 including GaN will be described as an example, but the present technology is not limited to GaN, and may include any of AlN, sapphire, or silicon carbide (Sic).

The first cladding layer 12 is formed to have a low refractive index in order to confine light emitted from an active layer 14 described later. The first cladding layer-12 includes, for example, AlGaN of n-type. The film thickness is, for example, more than or equal to 1000 nm.

The first light guide layer 13 is a layer formed between the first cladding layer 12 of n-type and the active layer 14 to confine light having a refractive index intermediate of both refractive indexes. The first light guide layer 13 includes InGaN, for example. Furthermore, the film thickness is, for example, more than or equal to 150 nm.

The active layer 14 is a light emitting region containing InGaN or the like that emits light having a wavelength corresponding to a band gap by recombination of electrons and positive holes. The active layer 14 may have a multi-quantum well (MQW) structure in addition to a quantum well (quantum well) structure. With the formation of the active layer 14 in the multi-quantum well structure, the number of layers that emit light increases, and thus a light emission intensity of the laser can be improved.

The second light guide layer 15 is a light guide layer formed on an upper surface of the active layer 14 such that the active layer 14 is sandwiched between the second light guide layer 15 and the first light guide layer 13 that confines light due to a difference in the refractive index. The second light guide layer 15 includes InGaN, for example, similarly to the first light guide layer 13. Furthermore, the film thickness is, for example, more than or equal to 150 nm.

The second cladding layer 18 is a p-type semiconductor layer formed on an upper surface of the intermediate layer 17 such that the active layer 14 is sandwiched with the second light guide layer 15 between the second cladding layer 18 and the first light guide layer 13 that confines light due to a difference in the refractive index.

The second cladding layer 18 includes, for example, AlGaN. Furthermore, the film thickness is, for example, more than or equal to 100 nm.

The contact layer 19 is a layer laminated on the upper surface of the second cladding layer 18 and electrically connected to the second electrode 20. In addition, the film thickness is more than or equal to 10 nm, and for example, a p-type GaN layer doped with Mg at 10²¹/cm³ or more is configured, and is in ohmic connection with the second electrode 20.

Although an example in which the contact layer 19 is connected to the second electrode has been described above, various materials can be used according to an electrode material formed on an upper part of the second electrode. For example, AlGaN, GaN, InGaN, or the like is desirable.

The second electrode 20 is formed on the upper surface of the ridge portion 30 where both side surfaces of the contact layer 19 and the second cladding layer 18 are removed by etching such as RIE, or the like. The second electrode 20 is an electrode of an anode for wire bonding wiring with one or more gold wires (Au) or the like, for example, in a mounting step which is a subsequent step.

The insulating layer 21 exposes an upper surface 20a of the second electrode 20, and for other than this, covers both side surface portions 30a and 30a of the ridge portion 30 and the upper surface of the second cladding layer 18, to provide electrical insulation. However, the covering of the insulating layer 21 is not limited to the above-described range. The upper surface 20a of the second electrode 20 not covered with the insulating layer 21 is subjected to the wire bonding wiring as described above. The configuration of the nitride semiconductor light emission element 100 according to the present disclosure is as described above.

### [Regarding Al Composition and Mg Concentration]

The Al composition and the Mg concentration of the p-type semiconductor layer of the nitride semiconductor light emission element 100 according to the present basic form configured as described above will be described below.

FIG. 3A and FIG. 3B are explanatory views illustrating a relationship between an Al composition and a Mg concentration of the second cladding layer 18 as the p-type semiconductor layer of the nitride semiconductor light emission element 100 according to the present basic form. That is, FIG. 3A is a diagram illustrating the relationship between the film thickness and the Al composition, and FIG. 3B is a diagram illustrating the relationship between the film thickness and the Mg concentration. Here, the film thickness on the horizontal axis in both drawings indicates a thickness (film thickness) of the p-type semiconductor layer that takes an upper surface of the active layer 14 as a growth start surface 52d of the second cladding layer 18 and grows upward from the growth start surface 52d. However, in both drawings, the illustration of layers of the contact layer 19 or above located on the further right side of the second cladding layer 18 is omitted. In addition, the growth start surface is an interface on the GaN substrate 11 side of the layer to grow, and growing of the film thickness (thickness) on the horizontal axis in the upward direction from the growth start surface is separating from the interface on the GaN substrate 11 side.

The basic form has a configuration in which the Al composition of the nitride semiconductor light emission element 100 according to the present basic form is inclined and decreased as the film thickness of the second cladding layer 18, which is the p-type semiconductor layer, increases as indicated by a straight line 50 in FIG. 3A. Furthermore, the Mg concentration of the nitride semiconductor light emission element 100 according to the present disclosure rapidly increases in the film thickness direction from the growth start surface 52d of the second cladding layer 18, which is a p-type semiconductor layer, to form a maximal value as indicated by a curve 52 in FIG. 3B. In this configuration, thereafter, the Mg concentration is configured to be inclined and reduced as the film thickness increases. That is, in this configuration, the Mg concentration decreases in conjunction with the Al composition after forming the maximal value 52a.

The nitride semiconductor light emission element 100 according to the present basic form is characterized in that the Al composition of the second cladding layer 18 is inclined and decreased in the film thickness direction, and the Mg concentration as a p-type impurity doped in the second cladding layer 18 is also inclined and reduced in the film thickness direction. This structure in which the Al composition and the Mg concentration of the second cladding layer 18 are simultaneously inclined and decreased in the film thickness direction is novel.

Conventionally, it has been known that when Mg as a p-type impurity is doped to be made p-type, laser characteristics are deteriorated by light absorption of Mg. Therefore, in order to improve laser characteristics, an approach of reducing the Mg concentration as much as possible has been taken. However, in a growth process by metal organic chemical vapor deposition (MOCVD), since there is a phenomenon that Mg adhering to a pipe or a chamber is taken into a crystal (memory effect) belatedly, it is difficult to cause the Mg concentration to be actually inclined and reduced in a growth direction.

The inventor of the present application has found, in the process of development, a phenomenon that Mg is easily incorporated into the crystal in synchronization with the Al composition (that is, the larger the Al composition, the higher the Mg concentration, and the smaller the Al composition, the lower the Mg concentration.). Therefore, it has been found that by growing a crystal while gradually reducing the Al composition of the second cladding layer 18, a crystal in which the Mg concentration is inclined and reduced in the growth direction can be achieved. With this method, the amount of Mg in the second cladding layer 18 can be controlled in more detail, and in the second cladding layer 18 having a single Al composition (see the horizontal straight line 51 in FIG. 3A) in the background art, it is possible to achieve that the Mg concentration is inclined and reduced in the film thickness direction, which is difficult to achieve only by controlling the supply amount of Mg.

The reason why the second cladding layer 18 can maintain p-type even with such a configuration is that when the Al composition in the AlGaN layer is reduced in the growth direction, a p-type AlGaN layer can be obtained (polarization doping), so that p-type formation can be performed even if the Mg concentration is inclined and reduced in the growth direction. The effect of polarization doping is stronger as the inclination of the Al composition is larger and the film thickness is thinner, and can be set to an optimum value according to characteristics of a device. In the present example, the Al composition was reduced by being inclined in the film thickness direction so that an initial value was 10% to 20% and a termination value was 0%, and the film thickness was achieved at 100 nm to 300 nm.

<2. First Modification of First Embodiment of Nitride Semiconductor Light Emission Element according to Present Disclosure>

### [Configuration of First Modification of First Embodiment]

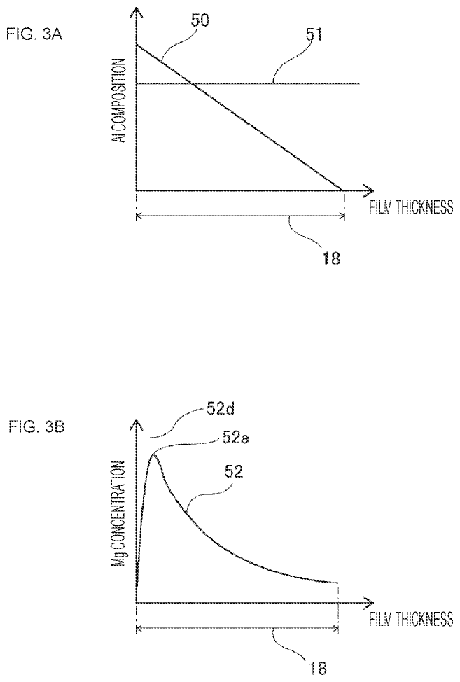

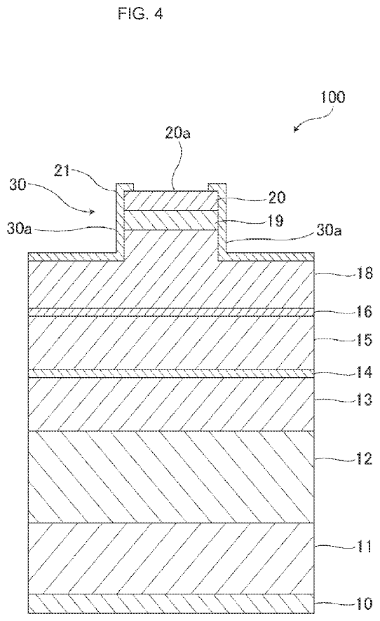

Hereinafter, the first modification of the first embodiment of the nitride semiconductor light emission element 100 according to the present disclosure will be described with reference to FIG. 4. Note that the plan view of the first modification is the same as that of FIG. 2. FIG. 4 is a cross-sectional view of the nitride semiconductor light emission element 100 according to the present first modification as viewed from the front end surface 24 side. The nitride semiconductor light emission element 100 according to the first modification is different from the basic form illustrated in FIG. 1 in that an electron barrier layer 16 is formed between the second light guide layer 15 and the second cladding layer 18.

The electron barrier layer 16 is an energy barrier configured to suppress electron overflow from the active layer 14 and promote recombination of electrons and holes in the active layer 14. The electron barrier layer 16 includes, for example, AlGaN. It is desirable that the electron barrier layer 16 is formed into an extremely thin layer having a film thickness of, for example, 5 nm to 10 nm. Furthermore, in order to increase an energy barrier of a conduction band, for example, magnesium (Mg) is doped at 10¹⁹/cm³ or more.

Other points than those described above are similar to the configuration of the basic form of the first embodiment, and thus description thereof will be omitted.

### [Regarding Al Composition and Mg Concentration]

The Al composition and the Mg concentration of the p-type semiconductor layer of the nitride semiconductor light emission element 100 according to the present first modification configured as described above will be described below.

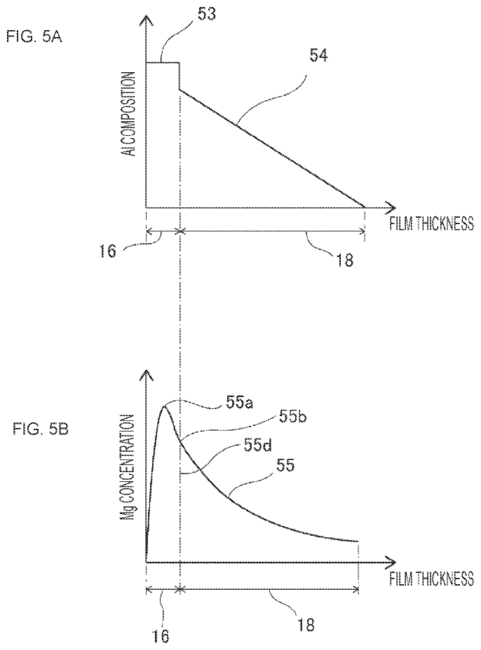

FIG. 5A and FIG. 5B are explanatory views illustrating a relationship between an Al composition and a Mg concentration of the electron barrier layer 16 and the second cladding layer 18 as the p-type semiconductor layers of the nitride semiconductor light emission element 100 according to the present first modification. That is, FIG. 5A is a diagram illustrating the relationship between the film thickness and the Al composition, and FIG. 5B is a diagram illustrating the relationship between the film thickness and the Mg concentration. Here, the film thickness on the horizontal axis in both drawings is similar to that described in the basic form of the first embodiment. Furthermore, similarly, in both drawings, the illustration of layers of the contact layer 19 or above located on the further right side of the second cladding layer 18 is omitted.

In the nitride semiconductor light emission element 100 according to the first modification, the Al composition of the electron barrier layer 16 as a p-type semiconductor layer is formed to have a constant value linearly and flatly with respect to the film thickness direction as indicated by a straight line 53 in FIG. 5A. In addition, the Mg concentration of the electron barrier layer 16 rapidly increases with respect to the film thickness direction to form a steep maximal value 55a, and then decreases rightward and downward as indicated by a curve 55 in FIG. 5B. Therefore, the growth start surface 55d of the second cladding layer 18, which is a surface in contact with the electron barrier layer 16, has the maximum value 55b.

The reason why the Mg concentration of the electron barrier layer 16 has the steep maximal value 55a as illustrated in FIG. 5B is that, for example, Mg is doped at 10¹⁹/cm³ or more in order to increase the energy barrier of the conduction band as described above.

The Al composition of the second cladding layer 18 laminated on the electron barrier layer 16 decreases from a straight line 53 to a straight line 54, and then is inclined and decreased in the film thickness direction as indicated by a straight line 54. Since a large amount of Mg is supplied in the growth process of the electron barrier layer 16, the Mg concentration of the second cladding layer 18 increases at the growth start surface 55d of the crystal of the second cladding layer 18 to form the maximum value 55b. Then, thereafter, even when the supply of Mg is stopped, Mg is taken into the crystal due to the memory effect. That is, the Mg concentration decreases as indicated by the curve 55 in FIG. 5B in conjunction with the Al composition being inclined and decreased in the film thickness direction as indicated by the straight line 54 in FIG. 5A.

As described above, the Mg concentration of each of the electron barrier layer 16 and the second cladding layer 18 is formed. With this formation, the electron barrier layer 16 suppresses the electron overflow from the active layer 14, and causes the Mg concentration to be inclined and reduced in a film thickness direction, deterioration of laser characteristics due to Mg light absorption can be suppressed.

<3. Second Modification of First Embodiment of Nitride Semiconductor Light Emission Element according to Present Disclosure>

### [Configuration of Second Modification of First Embodiment]

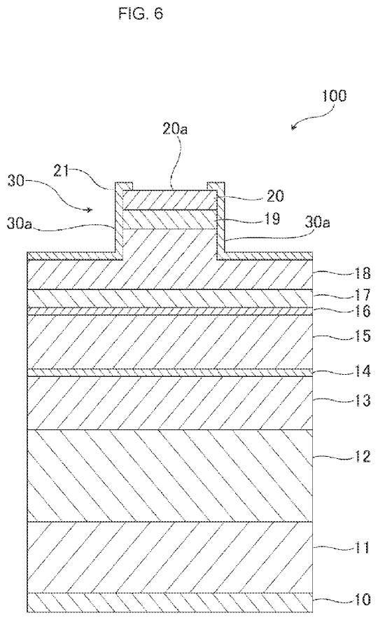

Hereinafter, the second modification of the first embodiment of the nitride semiconductor light emission element 100 according to the present disclosure will be described with reference to FIG. 6. Note that the plan view of the present second modification is the same as that of FIG. 2. FIG. 6 is a cross-sectional view of the nitride semiconductor light emission element 100 according to the present second modification as viewed from the front end surface 24 side. The nitride semiconductor light emission element 100 according to the second modification is different from the basic form illustrated in FIG. 1 in that an electron barrier layer 16 and an intermediate layer 17 are formed between the second light guide layer 15 and the second cladding layer 18.

Since the electron barrier layer 16 is similar to that in a case of the above-described first modification, the description thereof will be omitted.

The intermediate layer 17 is a layer for preventing generation of a fault laminated on the upper surface of the electron barrier layer 16. The intermediate layer 17 includes, for example, aluminum gallium nitride (AlGaN) including Al_{z}Ga_{(1-z)}N(0≤z<y<1) or indium gallium nitride (InGaN) including InₐGa₍₁₋ₐ₎N(0≤a≤1). In addition, the film thickness is more than or equal to 10 nm, for example, and Mg is doped at 10¹⁸/cm³ or more to configure p-type.

Here, the “fault” refers to, for example, a fine crack or the like generated in the vicinity of bonding surfaces of crystals such as GaN, AlGaN, InGaN, or the like. The crystals have different lattice constants and thus generate stresses at the bonding surfaces of them and when an external force such as cleavage of a wafer is added to the stresses, the crack or the like occurs.

The intermediate layer 17 is inserted between the second light guide layer 15 including InGaN and the second cladding layer 18 including AlGaN, and functions as a buffer zone that relaxes the stress caused by the difference in lattice constants between the second light guide layer 15 and the second cladding layer 18. Specifically, as described above, for example, the intermediate layer 17 includes aluminum gallium nitride (AlGaN) including Al_{z}Ga_{(1-z)}N(0≤z<y<1) or indium gallium nitride (InGaN) including InₐGa₍₁₋ₐ₎N(0≤a≤1), and an optimum value is obtained by adjusting the composition ratio z or the composition ratio a and the composition ratio of In of the second light guide layer 15.

Although detailed description is omitted, it is desirable to set z=0 or a=0 as an optimum value of the composition ratio z or the composition ratio a for relaxing the stress. That is, by adopting such a value, Al=0% or In=0%, and the intermediate layer 17 includes GaN.

Other points than those described above are similar to the configuration of the basic form of the first embodiment, and thus description thereof will be omitted.

### [Regarding Al Composition and Mg Concentration]

The Al composition and the Mg concentration of the p-type semiconductor layer of the nitride semiconductor light emission element 100 according to the present second modification configured as described above will be described below.

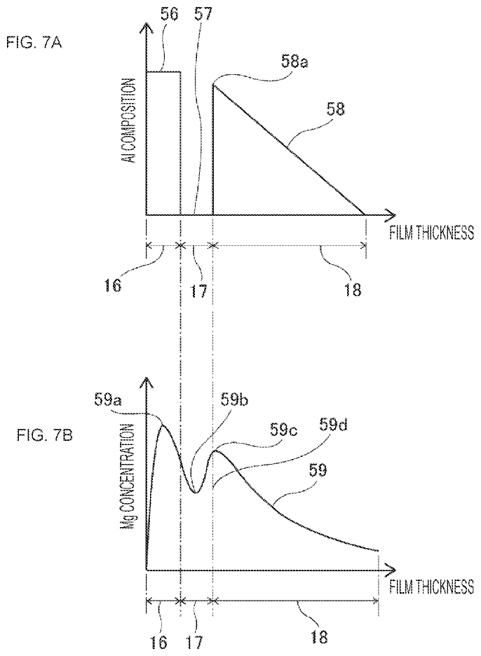

FIG. 7A and FIG. 7B are explanatory views illustrating a relationship between an Al composition and a Mg concentration of the electron barrier layer 16, and the intermediate layer 17, and the second cladding layer 18 as the p-type semiconductor layers of the nitride semiconductor light emission element 100 according to the present second modification. That is, FIG. 7A is a diagram illustrating the relationship between the film thickness and the Al composition, and FIG. 7B is a diagram illustrating the relationship between the film thickness and the Mg concentration. Here, the film thickness on the horizontal axis in both drawings is similar to that described in the basic form of the first embodiment. Furthermore, similarly, in both drawings, the illustration of layers of the contact layer 19 or above located on the further right side of the second cladding layer 18 is omitted.

In the nitride semiconductor light emission element 100 according to the second modification, the Al composition of the electron barrier layer 16 as a p-type semiconductor layer is formed to have a constant value linearly and flatly with respect to the film thickness direction as indicated by a straight line 56 in FIG. 7A. In addition, as indicated by a curve 59 in FIG. 7B, the Mg concentration of the electron barrier layer 16 rapidly increases with respect to the film thickness direction to form a steep maximal value 59a, and then decreases rightward and downward to reach a minimal value 59b described later. Then, the Mg concentration increases with a growth start of the second cladding layer 18, and reaches the maximum value at a growth start surface 59d of the second cladding layer 18 which is a surface in contact with the intermediate layer 17 or the maximal value 59c.

The Al composition of the intermediate layer 17 laminated on the electron barrier layer 16 is formed to be sharply smaller than the Al composition of the electron barrier layer 16. For example, the Al composition is zero (0) as indicated by a straight line 57 in FIG. 7A. On the other hand, since the Al composition rapidly decreases as indicated by the straight line 57 in FIG. 7A, in conjunction with this decrease, the Mg concentration of the intermediate layer 17 rapidly decreases from the maximal value 59a as indicated by the curve 59 in FIG. 7B, and reaches the minimal value 59b. As described above, the Al composition of the intermediate layer 17 is smaller than the Al composition of the electron barrier layer 16 and smaller than that of the growth start surface 59d of the second cladding layer 18 described later. In addition, the Al composition of the intermediate layer 17 is smaller than the average value of the Al composition of the second cladding layer 18.

The Al composition of the second cladding layer 18 laminated on the intermediate layer 17 becomes rapidly larger than that of the intermediate layer 17, and reaches the peak 58a from zero (0). It is desirable that the peak 58a is smaller than the straight line 56 of the Al composition of the electron barrier layer 16. Then, the Al composition is inclined and decreased from the peak 58a in the film thickness direction as indicated by a straight line 58 in FIG. 7A. On the other hand, since a large amount of Mg is supplied in the growth process of the electron barrier layer 16, the Mg concentration of the second cladding layer 18 is taken into the crystal due to the memory effect even if the supply of Mg is stopped. Therefore, when the growth of the second cladding layer 18 starts, the supply of Al is resumed, and the Al composition reaches the peak 58a as indicated by the straight line 58 in FIG. 7A, so that the Mg concentration also increases in conjunction with the increase in the Al composition, and reaches the maximal value 59c. The maximal value 59c is smaller than the maximal value 59a in the electron barrier layer 16. Then, the Mg concentration is inclined and reduced as indicated by the curve 59 in FIG. 7B in conjunction with the Al composition being inclined and decreased in the film thickness direction as indicated by the straight line 58. Therefore, the Mg concentration of the second cladding layer 18 becomes the maximum value at the growth start surface 59d or the maximal value 59c.

Since the present second modification is configured as described above, the Mg concentrations of the electron barrier layer 16, the intermediate layer 17, and the second cladding layer 18 can be formed in conjunction with the magnitude of the Al composition. With this formation, the electron barrier layer 16 can suppress the electron overflow from the active layer 14. In addition, it is possible to prevent the generation of the fault by providing the intermediate layer 17. Furthermore, since the Mg concentration is inclined and reduced in the film thickness direction, deterioration of laser characteristics due to light absorption of Mg can be suppressed.

<4. Manufacturing Method of First Embodiment of Nitride Semiconductor Light Emission Element according to Present Disclosure>

The nitride semiconductor light emission element 100 having the above-described configuration can be manufactured as follows, for example, in a case of the second modification of the first embodiment.

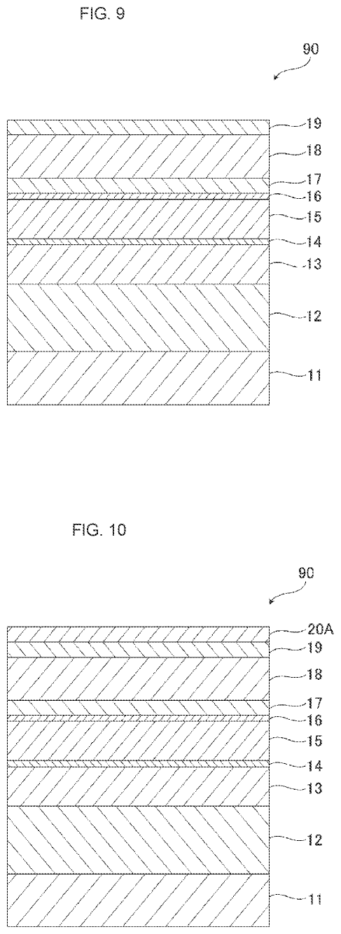

FIGS. 9 to 12 are schematic cross-sectional views illustrating a stack 90 of the second modification of the first embodiment in the order of steps when viewed from the front end surface 24 side as a light emission end surface. Note that, in the present specification, the stack 90 refers to the nitride semiconductor light emission element 100 that is being formed by laminating the GaN layer and the like sequentially.

### [Step of Forming Stack]

In the nitride semiconductor light emission element 100, first, as illustrated in FIG. 9, for example, the stack 90 is formed on the GaN substrate 11 by an MOCVD method. The stack 90 is formed by laminating the first cladding layer 12 of n-type, the first light guide layer 13, the active layer 14, the second light guide layer 15, the electron barrier layer 16, the intermediate layer 17, and the second cladding layer 18 in this order on the GaN substrate 11.

As a raw material for forming the nitride semiconductor light emission element 100, for example, trimethylaluminum (TMA), trimethylgallium (TMG), trimethylindium (TMIn), and ammonia (NH₃) is used. As a raw material of a donor impurity, for example, monosilane (SiH₄) is used. As a raw material of an acceptor impurity, for example, biscyclopentadienyl magnesium (Cp₂Mg) is used.

Specifically, in a case of an InGaN composition, TMIn, TMG, and NH₃ are used. Furthermore, in a case of an AlGaN composition, TMA, TMG, and NH₃ are used.

For example, in order to form the electron barrier layer 16 by increasing the Al composition, the supply of TMA is increased. In a case where the intermediate layer 17 is formed, the supply of the TMA is stopped. In order to cause the Al composition of the second cladding layer 18 to be inclined and decreased in the film thickness direction, the supply of the TMA is inclined and reduced from a predetermined value.

In addition, the doping amount of Mg for forming the p-type semiconductor layer is adjusted by increasing or decreasing the supply of Cp₂Mg. However, in the first embodiment, the p-type semiconductor layer is formed by utilizing polarization doping in which a p-type AlGaN layer can be obtained as the Al composition in the AlGaN layer is inclined and decreased in the film thickness direction. In addition, the p-type semiconductor layer is formed by utilizing a memory effect in which Mg is taken into the crystal in conjunction with the polarization doping. For this purpose, Cp₂Mg only need be supplied, for example, at the growth start of the electron barrier layer 16.

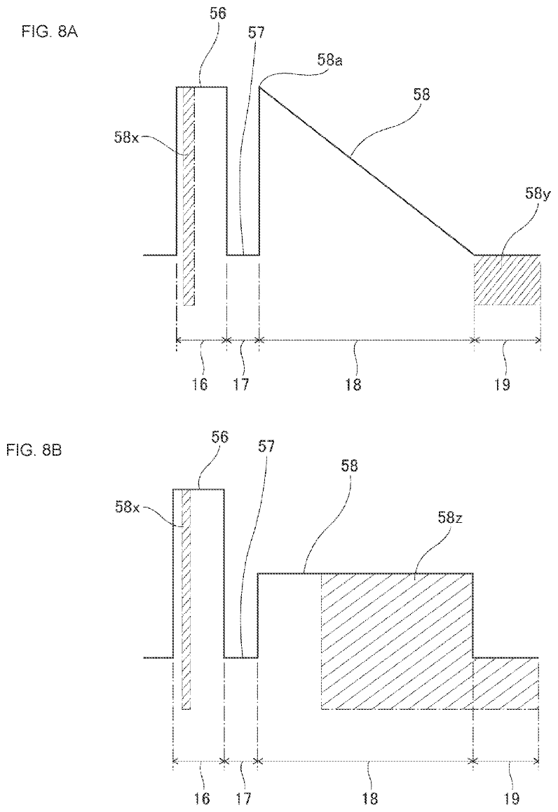

FIGS. 8A and 8B describe the above operation in more detail. FIG. 8A is an explanatory diagram corresponding to a straight line 58 in the explanatory diagram of FIG. 7A in the second modification. In FIG. 8A, Cp₂Mg is supplied in a region 58x substantially at the same time as the growth start of the electron barrier layer 16. Thereafter, the supply is stopped. However, even if the supply is stopped, Mg is taken into the crystal in conjunction with the Al composition due to the memory effect. Furthermore, p-type can be formed by causing the Al composition in the AlGaN layer to be inclined and decreased in the growth direction. Note that a region 58y at the right end in this drawing is doped with a large amount of Mg in order to form the contact layer 19 on the second cladding layer 18.

FIG. 8B is a diagram illustrating a comparative example with respect to FIG. 8A. The second cladding layer 18 of the comparative example in FIG. 8B is formed by a constant straight line 58 in which the Al composition in the AlGaN layer is flat with respect to the film thickness direction. Therefore, in a case of the comparative example, it is required to supply Cp₂Mg in the region 58z. This is because, since the polarization doping is not used, Mg needs to be supplied to form the p-type. This is similar to not only the second modification but also the basic form and the first modification.

### [Step of Forming Ridge Portion]

The ridge portion 30 is formed by etching the second cladding layer 18 and the contact layer 19 in the thickness direction by a dry etching method.

Specifically, as illustrated in FIG. 10, first, a pad layer 20A for forming the second electrode 20 is formed on the contact layer 19. After the pad layer 20A is formed on the entire surface by a vacuum vapor deposition method, an etching resist layer of a strip shape is formed on the pad layer 20A by a photolithography technique. Then, the pad layer 20A not covered with the etching resist layer is removed using aqua regia, and then the etching resist layer is removed. By such a step, the stack 90 illustrated in FIG. 11 can be obtained. Note that the second electrode 20 of a belt shape may be formed on the contact layer 19 by a lift-off method.

Note that where ER0 is an etching rate of the second electrode 20 and ER1 is an etching rate of the stack 90 when the second electrode 20 is patterned, it is desirable that ER0/ER1≥1×10, suitably ER0/ER1≥1×10² be satisfied. When ER0/ER1 satisfies such a relationship, it is possible to reliably pattern the second electrode 20 without etching the stack 90 (alternatively, by slight etching).

Next, using the second electrode 20 as an etching mask, the second cladding layer 18 and the contact layer 19 are etched in the thickness direction by the dry etching method to form the ridge portion 30. Specifically, both side surfaces of the second cladding layer 18 and the contact layer 19 are etched by the RIE method using the second electrode 20 as an etching mask to form the side surface portions 30a and 30a.

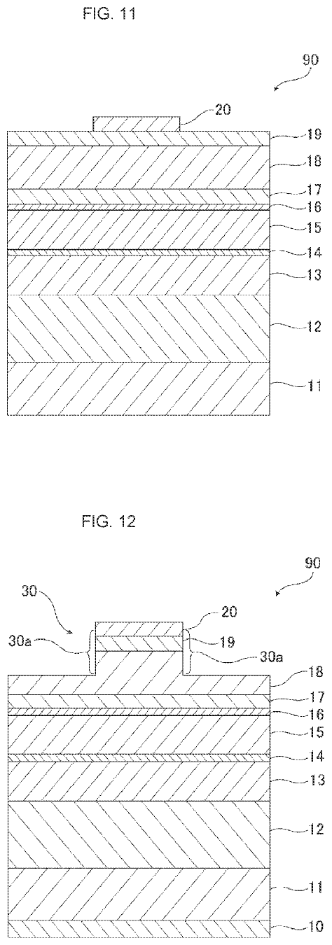

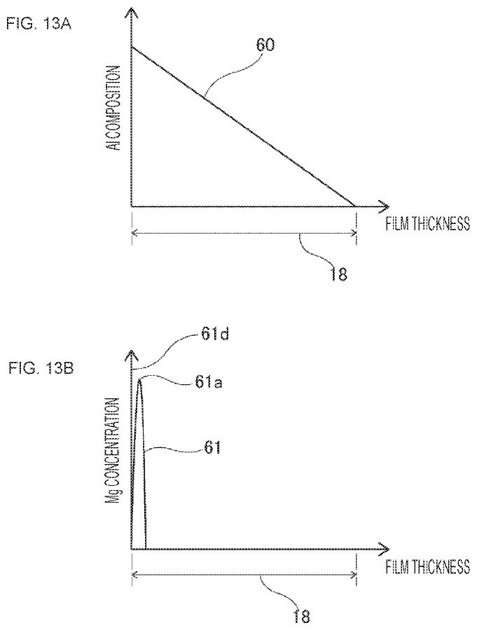

By such a step, the stack 90 illustrated in FIG. 12 can be obtained. As described above, since the ridge portion 30 is formed by a self-alignment method using the second electrode 20 patterned in a band shape as an etching mask, there is no occurrence of misalignment between the second electrode 20 and the ridge portion 30.

### [Step of Forming Insulating Layer and First Electrode]

Next, an insulation film is laminated on the entire upper surfaces of the ridge portion 30 and the second cladding layer 18, and the insulation film laminated on the second electrode 20 is removed. With this removal, the upper surface 20a of the second electrode 20 is exposed and the insulating layer 21 is formed on both side surface portions 30a and 30a of the ridge portion 30 and the upper surface of the second cladding layer 18.

Note that in order to improve heat dissipation property and wire bonding property of the nitride semiconductor light emission element 100 and wettability of a mounting solder bonding material or the like, a metal layer (not illustrated) may be formed on the insulating layer 21.

Furthermore, when the first electrode is formed, a back surface of the stack 90 is polished so as to have a thickness suitable for cleavage and mounting. When the polishing has been completed, an n-metal film is formed on the back surface by a vapor deposition method, a sputtering method, or the like, a pattern is formed by, for example, a lift-off method, and a first electrode 10 as a cathode is formed as shown in FIG. 12. With this formation, the stack 90 is formed.

Through the above steps, it is possible to obtain a wafer on which the nitride semiconductor light emission elements 100 illustrated in FIG. 6 are arranged.

### [Cleaving, Mounting and Inspection Step of Wafer]

Next, the wafer is cleaved in a cleaving step, inspected in an inspection step, and selected as a good product or a defective product. The nitride semiconductor light emission element 100 selected as a good product by the inspection is sent to a mounting step which is a next step. The nitride semiconductor light emission element 100 is packaged in the mounting step and is subjected to final inspection. In this way, the nitride semiconductor light emission element 100 according to the present embodiment can be manufactured.

As described above, with the manufacturing method of the first embodiment of the nitride semiconductor light emission element 100 according to the present disclosure, the amount of Cp₂Mg used can be reduced. Furthermore, since the Mg concentration of the second cladding layer 18 is inclined and reduced in the film thickness direction, deterioration of laser characteristics due to light absorption of Mg can be suppressed. In addition, since the Mg concentration can be controlled in conjunction with the Al composition by adjusting the Al composition, the Mg concentration can be easily controlled, and improvement of the productivity and improvement of the quality can be achieved.

Note that the manufacturing method of the basic form of the first embodiment is in a case where there is no step of forming the electron barrier layer 16 and the intermediate layer 17 between the second light guide layer 15 and the second cladding layer 18 in the manufacturing method described above. Furthermore, the manufacturing method of the first modification of the first embodiment is in a case where there is no step of forming the intermediate layer 17 between the second light guide layer 15 and the second cladding layer 18 in the manufacturing method described above.

Furthermore, the manufacturing method described above is merely an example, and the step order may be changed. In addition, it may be replaced with a new working method, a processing method, or new equipment.

<5. Second Embodiment of Nitride Semiconductor Light Emission Element according to Present Disclosure>

### [Configuration of Second Embodiment]

Hereinafter, the second embodiment of the nitride semiconductor light emission element 100 according to the present disclosure will be described. Note that a cross-sectional view illustrating a schematic structure of the present embodiment is the same as that in FIG. 1. Furthermore, the plan view is the same as that of FIG. 2. That is, the structure is similar to that of the basic form of the first embodiment, and thus description thereof is omitted.

### [Regarding Al Composition and Mg Concentration]

The Al composition and the Mg concentration of the p-type semiconductor layer of the nitride semiconductor light emission element 100 according to the second embodiment configured as described above will be described below.

FIG. 13A and FIG. 13B are explanatory views illustrating a relationship between an Al composition and a Mg concentration of the second cladding layer 18 as the p-type semiconductor layer of the nitride semiconductor light emission element 100 according to the present embodiment. That is, FIG. 13A is a diagram illustrating the relationship between the film thickness and the Al composition, and FIG. 13B is a diagram illustrating the relationship between the film thickness and the Mg concentration. Here, the film thickness on the horizontal axis in both drawings is similar to that described in the basic form of the first embodiment. Furthermore, similarly, in both drawings, the illustration of layers of the contact layer 19 or above located on the further right side of the second cladding layer 18 is omitted.

The present embodiment has a configuration in which the Al composition of the nitride semiconductor light emission element 100 according to the present basic form is inclined and decreased as the film thickness of the second cladding layer 18 increases as indicated by a right-down straight line 60 in FIG. 13A. Furthermore, in this configuration, the Mg concentration of the nitride semiconductor light emission element 100 according to the present embodiment rapidly increases from the growth start surface 61d of the second cladding layer 18 and has a steep maximal value 61a as indicated by a curve 61 in FIG. 13B, and then rapidly decreases to be non-doped.

That is, in the nitride semiconductor light emission element 100 according to the present embodiment, the Al composition of the second cladding layer 18 is inclined and decreased in the film thickness direction. In addition, the Mg concentration as the p-type impurity doped in the second cladding layer 18 rapidly increases from the growth start surface 61d to form a steep maximal value 61a, and then rapidly decreases. That is, the nitride semiconductor light emission element 100 according to the present embodiment has a structure in which the Al composition of the second cladding layer 18 is inclined and decreased in the film thickness direction, and the Mg concentration thereof rapidly increases and decreases from the crystal growth start surface 61d to be non-doped as indicated by the curve 61.

In the nitride semiconductor light emission element 100 according to the present embodiment, Mg is doped in the growth start surface 61d of the second cladding layer 18, and the second cladding layer 18 is formed in the p-type semiconductor layer by using polarization doping in the subsequent growth process.

With the configuration described above, it is possible to exert effects similar to those described in the second modification of the first embodiment. Moreover, the amount of Cp₂Mg used can be further reduced. Furthermore, since the Mg concentration is reduced, deterioration of laser characteristics due to light absorption of Mg can be further suppressed.

<6. Manufacturing Method of Second Embodiment of Nitride Semiconductor Light Emission Element according to Present Disclosure>

The nitride semiconductor light emission element 100 of the second embodiment having the above-described configuration can be manufactured as follows, for example. However, the manufacturing method of the nitride semiconductor light emission element 100 according to the second embodiment has common points with the manufacturing method of the first embodiment, and thus differences from the manufacturing method of the first embodiment will be described.

First, at the start of lamination of the second cladding layer 18, TMA, TMG, and NH₃ are supplied to grow the AlGaN layer, and the Al composition is decreased in an inclined manner in the film thickness direction while the supply of TMA is adjusted. At the same time, Cp₂Mg is supplied to dope Mg, and the Mg concentration is rapidly increased as shown in the curve 61 of FIG. 13B. Then, when the film thickness reaches several nm, for example, the supply of Cp₂Mg is stopped, and the growth of the second cladding layer 18 is temporarily interrupted. Therefore, the Mg concentration reaches the maximal value 61a and then rapidly decreases.

Next, a wafer of the stack 90 is taken out from a crystal growth device (not illustrated), Mg in a growth furnace is depleted, and then the wafer of the stack 90 is set again in the crystal growth device to resume the crystal growth of the second cladding layer 18.

After the resuming, the supply of Cp₂Mg is kept stopped. Therefore, in a state where Mg is not supplied and Mg in the growth furnace is depleted, Mg is not incorporated into the crystal due to the memory effect. That is, the crystal of AlGaN of the second cladding layer 18 is made to grow in a state where Mg is not doped. At the same time, the Al composition is inclined and decreased in the film thickness direction while the supply amount of TMA is adjusted.

By performing the manufacturing step as described above, a p-type semiconductor layer including the second cladding layer 18 having a low Mg concentration can be formed.

Note that the regrowth of the second cladding layer 18 may be performed using the same device as described above, but may be performed in combination with another device. For example, the regrowth may be performed with a plurality of devices of different growth methods such as an MOCVD device, an MBE device, and a sputtering device combined.

Since the points other than those described above are similar to the manufacturing method of the first embodiment of the nitride semiconductor light emission element 100, the description thereof will be omitted.

In the nitride semiconductor light emission element 100 according to the present embodiment, Mg is supplied and doped at the growth start of the second cladding layer 18, and the supply of Mg is stopped in a state where Mg in the growth furnace is depleted in a subsequent growth process of the second cladding layer 18 of AlGaN. That is, in the growth of the crystal of the AlGaN layer, the second cladding layer 18 is formed in the p-type semiconductor layer by using polarization doping without using the memory effect of Mg.

By adopting the manufacturing method described above, it is not necessary to adjust the Mg concentration in the growth of the crystal of the AlGaN layer, so that the manufacturing process is simplified. Furthermore, by adopting such a manufacturing method, it is possible to exert effects similar to those described in the second modification of the first embodiment. Moreover, the amount of Cp₂Mg used can be further reduced. Furthermore, since the Mg concentration can be also decreased, deterioration of laser characteristics due to light absorption of Mg can be further suppressed.

Finally, the description of each of the above-described embodiments is an example of the present disclosure, and the present disclosure is not limited to the above-described embodiments. For this reason, it is needless to say that various modifications other than each of the above-described embodiments can be made according to the design and the like without departing from the technical idea according to the present disclosure. Furthermore, the effects described in the present specification are merely examples and are not limited thereto, and other effects may be further provided.

Note that the present technology can also have the following configuration.

(1)

A nitride semiconductor light emission element including:
a substrate having a (0001) plane as a lamination plane;
an n-type semiconductor layer;
an active layer;
a p-type semiconductor layer; and
a contact layer in this order,
the p-type semiconductor layer including a cladding layer including AlGaN, in which
an Al composition of the cladding layer is formed to be smaller as being away from an interface on the substrate side, and
a Mg concentration of the cladding layer is formed to have a maximum value at the interface on the substrate side or a maximal value in a direction of being away from the interface on the substrate side.
   (2)

The nitride semiconductor light emission element according to the (1), in which the Mg concentration of the cladding layer is formed to decrease from the maximum value or the maximal value as being away from the interface on the substrate side.

(3)

The nitride semiconductor light emission element according to the (1) or the (2), in which
the p-type semiconductor layer includes an electron barrier layer including AlGaN, and
the Mg concentration of the cladding layer is formed to have a maximum value on a surface in contact with the electron barrier layer.
   (4)

The nitride semiconductor light emission element according to the (3), in which the Mg concentration of the cladding layer is formed to decrease from the maximum value formed on a surface in contact with the electron barrier layer as being away from the interface on the substrate side.

(5)

The nitride semiconductor light emission element according to the (1), in which
the p-type semiconductor layer includes
an electron barrier layer including AlGaN, and
an intermediate layer including AlGaN in order closer to the substrate having the (0001) plane as the lamination plane than to the cladding layer, and
the Mg concentration in the cladding layer is formed such that either of maximal values in a direction away from the surface in contact with the intermediate layer or the interface on the substrate side makes a maximum value.
   (6)

The nitride semiconductor light emission element according to the (5), in which the Mg concentration of the cladding layer is formed to decrease as being away from the surface in contact with the intermediate layer or decreased as being away from the interface on the substrate side from the maximal value.

(7)

The nitride semiconductor light emission element according to the (5) or the (6), in which
the Al composition of the intermediate layer is formed to be smaller than the Al composition of the electron barrier layer and
smaller than the Al composition of the interface of the cladding layer on the substrate side.
   (8)

The nitride semiconductor light emission element according to any of the (5) to the (7), in which the Al composition of the intermediate layer is formed to be smaller than the Al composition of the electron barrier layer and smaller than an average value of the Al composition of the cladding layer.

(9)

A nitride semiconductor light emission element including:
a substrate having a (0001) plane as a lamination plane;
an n-type semiconductor layer;
an active layer;
a p-type semiconductor layer; and
a contact layer in this order,
the p-type semiconductor layer including an electron barrier layer including AlGaN, an intermediate layer including GaN, and a cladding layer including AlGaN, in which
an Al composition of the cladding layer is formed to be smaller as being away from an interface on the substrate side, and
a Mg concentration of the cladding layer is formed to have a maximum value at the interface on the substrate side or a maximal value in a direction of being away from the interface on the substrate side.
   (10)

A nitride semiconductor light emission element including:
a substrate having a (0001) plane as a lamination plane;
an n-type semiconductor layer, an active layer;
a p-type semiconductor layer; and
a contact layer in this order,
the p-type semiconductor layer including a cladding layer including AlGaN, in which
an Al composition of the cladding layer is formed to be smaller as being away from an interface on the substrate side, and
a Mg concentration of the cladding layer rapidly increases to form a maximal value from the interface on the substrate side, and
rapidly decreases to be non-doped from the maximal value.
   (11)

The nitride semiconductor light emission element according to any of the above (1) to (10), in which the substrate having the (0001) plane as the lamination plane includes any of aluminum nitride (AlN), gallium nitride (GaN), sapphire, or silicon carbide (SiC).

### REFERENCE SIGNS LIST

10 First electrode
11 GaN substrate (substrate having (0001) plane as lamination plane)
12 First cladding layer
13 First light guide layer
14 Active layer
15 Second light guide layer
16 Electron barrier layer
17 Intermediate layer
18 Second cladding layer
19 Contact layer
21 Insulating layer
24 Front end surface
25 Rear end surface
30 Ridge portion
50 to 61 Straight line or curve in the drawing
90 Stack
100 Nitride semiconductor light emission element

1. A nitride semiconductor light emission element comprising:
a substrate having a (0001) plane as a lamination plane;
an n-type semiconductor layer;
an active layer;
a p-type semiconductor layer; and
a contact layer in this order,
the p-type semiconductor layer including a cladding layer including AlGaN, wherein
an Al composition of the cladding layer is formed to be smaller as being away from an interface on the substrate side, and
a Mg concentration of the cladding layer is formed to have a maximum value at the interface on the substrate side or a maximal value in a direction of being away from the interface on the substrate side.

2. The nitride semiconductor light emission element according to claim 1, wherein the Mg concentration of the cladding layer is formed to decrease from the maximum value or the maximal value as being away from the interface on the substrate side.

3. The nitride semiconductor light emission element according to claim 1, wherein
the p-type semiconductor layer includes an electron barrier layer including AlGaN, and
the Mg concentration of the cladding layer is formed to have a maximum value on a surface in contact with the electron barrier layer.

4. The nitride semiconductor light emission element according to claim 3, wherein the Mg concentration of the cladding layer is formed to decrease from the maximum value formed on a surface in contact with the electron barrier layer as being away from the interface on the substrate side.

5. The nitride semiconductor light emission element according to claim 1, wherein
the p-type semiconductor layer includes
an electron barrier layer including AlGaN, and
an intermediate layer including AlGaN in order closer to the substrate having the (0001) plane as the lamination plane than to the cladding layer, and
the Mg concentration in the cladding layer is formed such that either of maximal values in a direction away from the surface in contact with the intermediate layer or the interface on the substrate side makes a maximum value.

6. The nitride semiconductor light emission element according to claim 5, wherein the Mg concentration of the cladding layer is formed to decrease as being away from the surface in contact with the intermediate layer or decreased as being away from the interface on the substrate side from the maximal value.

7. The nitride semiconductor light emission element according to claim 5, wherein
the Al composition of the intermediate layer is formed to be smaller than the Al composition of the electron barrier layer and
smaller than the Al composition of the interface of the cladding layer on the substrate side.

8. The nitride semiconductor light emission element according to claim 5, wherein the Al composition of the intermediate layer is formed to be smaller than the Al composition of the electron barrier layer and smaller than an average value of the Al composition of the cladding layer.

9. A nitride semiconductor light emission element comprising:
a substrate having a (0001) plane as a lamination plane;
an n-type semiconductor layer;
an active layer;
a p-type semiconductor layer; and
a contact layer in this order,
the p-type semiconductor layer including an electron barrier layer including AlGaN, an intermediate layer including GaN, and a cladding layer including AlGaN, wherein
an Al composition of the cladding layer is formed to be smaller as being away from an interface on the substrate side, and
a Mg concentration of the cladding layer is formed to have a maximum value at the interface on the substrate side or a maximal value in a direction of being away from the interface on the substrate side.

10. A nitride semiconductor light emission element comprising:
a substrate having a (0001) plane as a lamination plane;
an n-type semiconductor layer, an active layer;
a p-type semiconductor layer; and
a contact layer in this order,
the p-type semiconductor layer including a cladding layer including AlGaN, wherein
an Al composition of the cladding layer is formed to be smaller as being away from an interface on the substrate side, and
a Mg concentration of the cladding layer rapidly increases to form a maximal value from the interface on the substrate side, and
rapidly decreases to be non-doped from the maximal value.

11. A nitride semiconductor light emission element according to claim 1, wherein the substrate having the (0001) plane as the lamination plane includes any of aluminum nitride (AlN), gallium nitride (GaN), sapphire, or silicon carbide (SiC).
